(19) United States
(12) Patent Application Publication
(10) Pub. No.: US 2011/0159183 A1
(43) Pub. Date: Jun. 30, 2011

(54) CHEMICAL VAPOR DEPOSITION APPARATUS AND A CONTROL METHOD THEREOF

(75) Inventor: Joo Jin, Yongin-City (KR)

(73) Assignee: LIGADP CO., LTD.

(21) Appl. No.: 12/914,928

(22) Filed: Oct. 28, 2010

(30) Foreign Application Priority Data
Dec. 24, 2009 (KR) 10-2009-0131039
Feb. 5, 2010 (KR) 10-2010-0011141

(51) Int. Cl. C23C 16/52; C23C 16/455; C23C 16/458; C23C 16/46

(52) U.S. Cl. 427/248.1; 118/712

(57) ABSTRACT

Disclosed are a chemical vapor deposition (CVD) apparatus and a control method thereof, the CVD apparatus including: a chamber; a susceptor which is provided inside the chamber and on which a substrate is placed; a process-gas supplying unit which is placed above the susceptor and supplies process gas; a sensing tube which is placed above the susceptor and opened toward the susceptor or the substrate; a temperature sensing member which is installed at a side of the sensing tube and senses temperature of the susceptor or substrate through the sensing tube; and a purge-gas supplying unit which injects purge gas into the sensing tube.

### CROSS-REFERENCE TO RELATED APPLICATIONS

This application claims the benefit of priority of Korean Patent Application No. 10-2010-0011141, filed on Feb. 5, 2010, and No. 10-2009-0131039, filed on Dec. 24, 2009, the disclosure of which is incorporated herein in its entirety by reference.

### BACKGROUND

1. Technical Field

The present invention provides a chemical vapor deposition (CVD) apparatus and a control method thereof, and more particularly to a CVD apparatus provided with a sensing tube through that thermometer can sense the temperature of a susceptor and a substrate without contact, and a control method thereof.

2. Related Art

A chemical vapor deposition (CVD) apparatus is an apparatus for depositing a thin film on a wafer. In particular, a metal organic chemical vapor deposition (MOCVD) apparatus is an apparatus for depositing a gallium nitride thin film on a substrate by supplying group III and V compounds into a chamber.

To deposit the gallium nitride thin film, the MOCVD apparatus performs processes under a high temperature of 600 ˜1300. Due to the high temperature, it is difficult to use a contact type thermometer to a substrate or a susceptor.

Accordingly, the MOCVD apparatus employs a non-contact type thermometer such as an infrared thermometer or an optical pyrometer.

Further, the CVD apparatus is provided with a sensing tube, which passes therethrough, between the non-contact type thermometer and a process room such that the non-contact type thermometer at the outside of the process room can sense temperature of a substrate placed inside the process room.

However, some process gas may flow back into the sensing tube during the process since the sensing tube communicates with the process room. If the process gas is deposited on the inner wall of the sensing tube, it may block the sensing tube or have an to effect on sensing the temperature.

### SUMMARY OF THE DISCLOSURE

The present invention provides a chemical vapor deposition (CVD) apparatus and a control method thereof, in which purge gas is injected toward a substrate or a susceptor through a sensing tube so as to prevent process gas from being introduced in the sensing tube.

In an aspect, a chemical vapor deposition (CVD) apparatus includes: a chamber; a susceptor which is provided inside the chamber and on which a substrate is placed; a process-gas supplying unit which is placed above the susceptor and supplies process gas; a sensing tube which is placed above the susceptor and opened toward the susceptor or the substrate; a temperature sensing member which is installed at an end of the sensing tube and senses temperature of the susceptor or the substrate through the sensing tube; and a purge-gas supplying unit which injects purge gas into the sensing tube.

In another aspect, a chemical vapor deposition (CVD) apparatus includes: a chamber; a susceptor which is provided inside the chamber and on which a substrate is placed; a process-gas supplying unit which is placed above the susceptor and supplies process gas; a sensing tube which is placed above the susceptor and opened toward the susceptor or the substrate; a temperature sensing member which is installed at an end of the sensing tube and senses temperature of the susceptor or the substrate through the sensing tube; a first purge-gas supplying unit which injects first purge gas into the sensing tube; and a second purge-gas supplying unit which injects second purge gas into the sensing tube.

In still another aspect, a method of controlling a chemical vapor deposition (CVD) apparatus includes: placing a substrate on a susceptor provided inside a chamber; heating the substrate and the susceptor; injecting process gas into the chamber; injecting purge gas into a sensing tube; and sensing temperature of the substrate or susceptor through the sensing tube.

### BRIEF DESCRIPTION OF THE DRAWINGS

FIG. 1 shows a sectional view of a chemical vapor deposition (CVD) apparatus according to a first exemplary embodiment of the present invention;

FIG. 2 shows a sectional view of a sensing tube in the CVD apparatus according to the first exemplary embodiment of the present invention;

FIG. 3 shows a sectional view of a CVD apparatus according to a second exemplary embodiment of the present invention;

FIG. 4 shows a sectional view of a sensing tube in the CVD apparatus according to the second exemplary embodiment of the present invention; and

FIG. 5 is a flowchart of a control method of the CVD apparatus according to an exemplary embodiment of the present invention.

### DETAILED DESCRIPTION OF DISCLOSURE

Reference will now be made in detail to the preferred embodiment of the present invention, examples of which are illustrated in the drawings attached hereinafter, wherein like reference numerals refer to like elements throughout. The embodiments are described below so as to explain the present invention by referring to the figures.

Below, a chemical vapor deposition (CVD) apparatus will be described according to a first exemplary embodiment of the present invention.

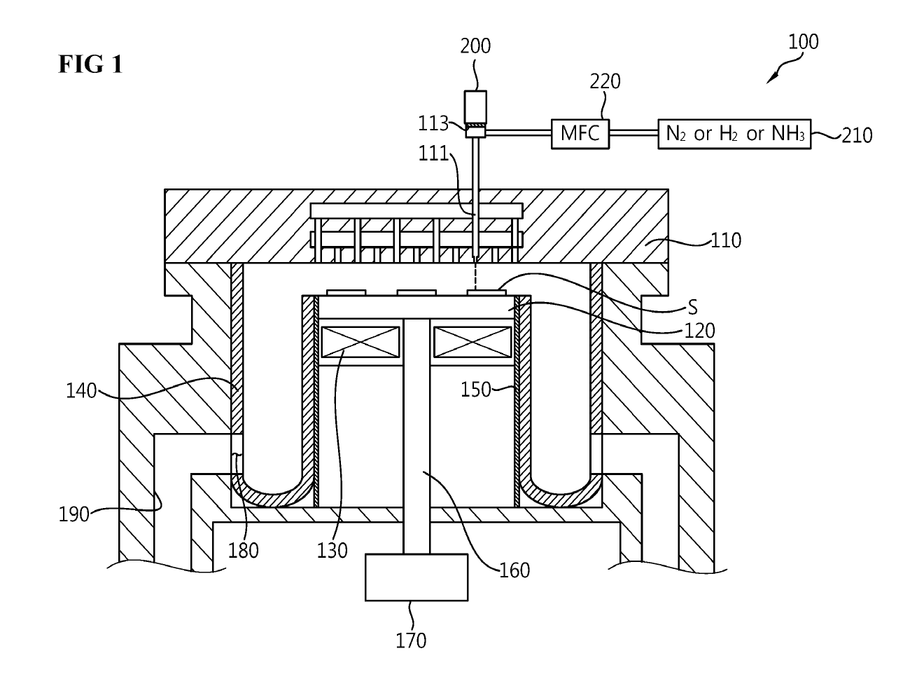

FIG. 1 shows a sectional view of the CVD apparatus according to the first exemplary embodiment of the present invention. As shown in FIG. 1, a metal organic chemical vapor deposition (MOCVD) apparatus in this embodiment includes a chamber 100 forming an outer appearance. Further, a process-gas supplying unit 110 is provided at an upper inside of the chamber 100 and injects group III and V gas into the chamber 100.

The process-gas supplying unit 110 may be implemented by a shower head that includes a first process-gas supplying channel 114, a second process-gas supplying channel 115 and a cooling channel 116. The second process-gas supplying channel 115 is provided separately from the first process-gas supplying channel 114 so that first process gas and second process gas cannot be mixed with each other. Each of the first process-gas supplying channel 114 and the second process-gas supplying channel 115 is formed to cross the cooling channel 115. Through the cooling channel 116, cooling water flows and lowers temperature at a bottom of the shower head. This is to prevent the process gas from reaction at the bottom of the shower head.

Alternatively, the process-gas supplying unit 110 may be achieved in the form of a nozzle.

A susceptor is provided under the process-gas supplying unit 110. A plurality of substrates S may be placed on the susceptor 120. A rotating shaft 160 may be provided beneath the susceptor 120, and a motor 170 may be mounted to a lower end of the rotating shaft 160 extended to an outside of the chamber 100. In this case, the susceptor 120 is rotated by the rotating shaft 160 and the motor 170 installed outside the chamber 100 while process is performed.

In the chamber 100, a heater 130 for heating the susceptor 120 may be installed beneath the susceptor 120. The heater 130 may be provided in plural. The heater 130 may heat the substrate S placed on the susceptor 120 to have a temperature of 600 ˜1300. Here, a tungsten heater, a radio frequency (RF) heater or the like may be used as the heater 130.

A partition wall 150 may be provided at lateral sides of the susceptor 120 and the heater 130 and extended to a bottom of the chamber 100. Further, a liner 140 having a ‘J’-shape may be installed between the partition wall 150 and an inner wall of the chamber 100. The liner 140 prevents particles from being deposited on the inside of the chamber 100 and the partition wall 150. Here, the liner 140 may be made of quartz. In this exemplary embodiment, a user may select whether to use the liner 140.

In a lower part of the chamber 100 is formed an exhaust pipe 190 through which gas and particles remaining after the process can be exhausted. The exhaust pipe 190 communicates with a hole 180 formed in the liner 140. Thus, the gas and particles remaining after the process are guided by the liner 140 and exhausted through the exhaust pipe 190. Further, a pump (not shown), a gas scrubber (not shown) for purging exhaust gas, etc. may be installed in the exhaust gas 190.

Meanwhile, as shown in FIG. 1, a non-contact type thermometer 200 may be installed at an upper outside of the process-gas supplying unit 110 as a temperature sensing member for sensing temperature of the substrate S or the susceptor 120 inside the chamber 100. Although it is not shown, the non-contact type thermometer may be installed at an upper cover of the chamber 100. Further, a sensing tube 111 is provided in the process-gas supplying unit 110 such that the non-contact type thermometer 200 can sense the temperature of the substrate S or susceptor 120 at an outside of a process room.

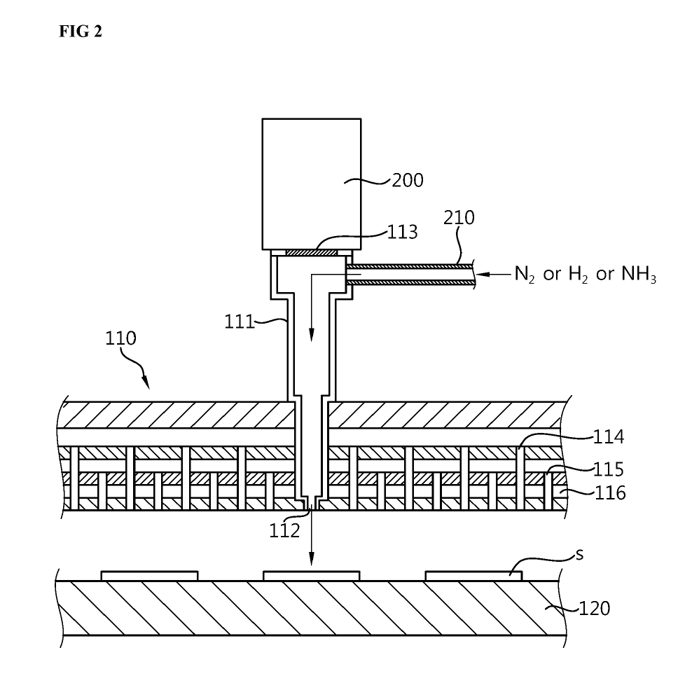

Below, the non-contact type thermometer 200 and the sensing tube 111 according to the first exemplary embodiment will be described in detail. FIG. 2 shows a sectional view of a sensing tube in the CVD apparatus according to the first exemplary embodiment of the present invention.

During the process, the inside of the chamber 100 where the substrate S or the susceptor 120 is placed, i.e., the process room increases in temperature up to 1300° C. Therefore, the non-contact type thermometer 200 is employed as the temperature sensing member for sensing the temperature of the substrate S or the susceptor 120, which is installed outside the process room as shown in FIG. 2.

As the non-contact type thermometer 200, there may be used an optical pyrometer that measures temperature by comparing brightness of an object with reference brightness, or an infrared thermometer that senses temperature based on infrared energy radiated from an object.

The sensing tube 111 is provided penetrating between the non-contact type thermometer 200 and the process room so that the non-contact type thermometer 200 installed outside the process room can sense the temperature of the substrate S or the susceptor 120 placed inside the process room.

As shown in FIG. 2, the sensing tube 111 may pass through the shower head used as the process-gas supplying unit 110.

The non-contact type thermometer 200 is placed at an upper end of the sensing tube 111. Further, an outlet 112 forming a lower end of the sensing tube 111 is opened toward the susceptor 120. The outlet 112 of the sensing tube 111 may be formed to have a diameter smaller than an inner diameter of a body of the sensing tube 111.

However, the process gas may flow back into the sensing tube 111 through the outlet 112 of the sensing tube 111 since the outlet 112 of the sensing tube 111 communicates with the process room. If the process gas is introduced into the sensing tube 111, it may be deposited on an inner wall of the sensing tube 111 and a lens part of the non-contact type thermometer 200. Further, it may block the sensing tube 111.

Particularly, if the process gas introduced into the sensing tube 111 is deposited on the lens part of the non-contact type thermometer 200, there may be a large error in a sensed temperature.

Thus, the CVD apparatus according to the first exemplary embodiment of the present invention is provided with a purge-gas supplying unit 210 at one side of an upper part of the sensing tube 111 so as to inject purge gas into the sensing tube 111. During the process, the purge-gas supplying unit 210 continuously supplies purge gas to inside of the sensing tube 111. The purge gas injected into the sensing tube 111 is continuously discharged through the outlet 112 of the sensing tube 111 and prevents the process gas from being introduced through the outlet 112 of the sensing tube 111. At this time, inert gas such as nitrogen or hydrogen may be used as the purge gas.

If the inert gas is employed as the purge gas, it does not affect a processing condition inside the chamber 100. However, an excessively large amount of purge gas may vary the processing condition. On the other hand, an excessively small amount of purge gas may not be enough to prevent foreign materials from being introduced through the outlet 112 of the sensing tube 111.

Accordingly, the purge-gas supplying unit 210 according to an exemplary embodiment of the present invention may be configured to have a controller 220 such as a mass flow controller (MFC) or auto pressure controller (APC) for controlling the flow or pressure of the purge gas to be injected into the sensing tube 111. In this case, the flow or pressure of the purge gas may be properly varied depending on the processes. The controller 220 may be provided according to a user's selection.

Meanwhile, ammonia gas for the process gas may be used as the purge gas supplied by the purge-gas supplying unit 210. Since the ammonia gas itself is the process gas, there is no effect on an epitaxial process even though a large amount of ammonia gas is injected through the sensing tube 111.

In the case that the ammonia gas is supplied as the purge gas, the purge-gas supplying unit 210 may be provided with the controller 220 such as the MFC or APC for controlling the amount of ammonia gas injected into the sensing tube 111, thereby supplying the ammonia gas at a proper pressure based on the process.

The reason why the ammonia gas is injected through the sensing tube 111 in the present exemplary embodiment is because the CVD apparatus in this exemplary embodiment is implemented by the MOCVD apparatus for using group III and V reaction gas to deposit a gallium nitride layer. Therefore, if the process gas is different, different process gas may be injected through the sensing tube 111.

In the meantime, foreign materials may be introduced and attached to a lens part placed in a front end of the non-contact type thermometer 200 at a time when the purge gas is not supplied or a process ambient is changed.

Accordingly, a window 113 may be provided between the sensing tube 111 and the non-contact type thermometer 200 so that a foreign material can be prevented from being directly attached to an object lens.

The window 113 may contain quartz or the like excellent in strength and resistance to chemicals. Also, the non-contact type thermometer 200 may be detachably installed at upside of the sensing tube 111, and the window 113 may be detachably mounted between an upper end of the sensing tube 111 and the non-contact type thermometer 200. In this case, it is possible to periodically clean foreign materials attached to the window 113 by separating the window 113 after the non-contact type thermometer 200 is detached from the sensing tube 111.

Below, a chemical vapor deposition (CVD) apparatus will be described according to a second exemplary embodiment of the present invention.

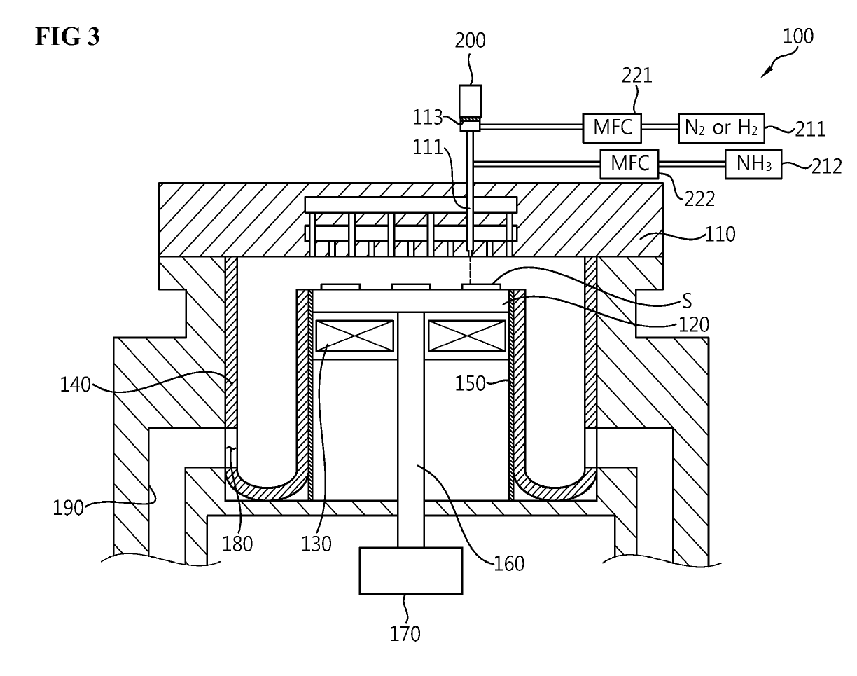

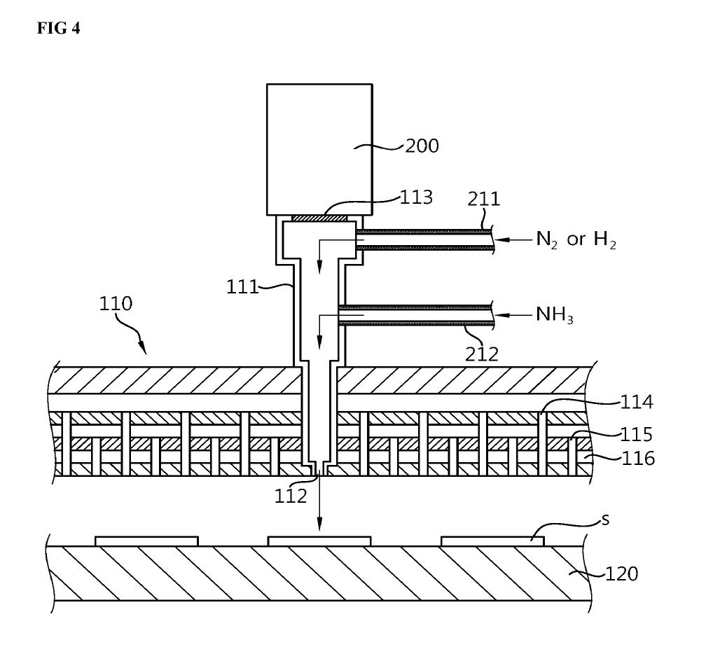

FIG. 3 shows a sectional view of the CVD apparatus according to the second exemplary embodiment of the present invention. FIG. 4 shows a sectional view of a sensing tube in the CVD apparatus according to the second exemplary embodiment of the present invention. As compared with the first exemplary embodiment, like numerals refer to like elements and repetitive descriptions will be avoided for convenience of description.

The CVD apparatus in the first exemplary embodiment is provided with the purge-gas supplying unit 210 at one side of an upper part of the sensing tube 111 so as to inject the purge gas into the sensing tube 111 (refer to FIGS. 1 and 2). Further, the purge gas supplied by the purge-gas supplying unit 210 is configured to selectively use one among nitrogen gas, hydrogen gas and ammonia gas.

On the contrary, the CVD apparatus in the second exemplary embodiment is separately provided with a first purge-gas supplying unit 211 and a second purge-gas supplying unit 212 to respectively inject different kinds of purge gas into the sensing tube 111 (refer to FIGS. 3 and 4).

The first purge-gas supplying unit 211 is provided at one side of a upper part of the sensing tube 111 and injects first purge gas into the sensing tube 111. Inert gas such as nitrogen or hydrogen may be used as the first purge gas. As necessary, the first purge-gas supplying unit 211 may be provided with a first controller 221 such as a mass flow controller (MFC) or auto pressure controller (APC) for control the flow or pressure of the first purge gas to be injected into the sensing tube 111, so that the flow or pressure of the first purge gas can be controlled according to processes.

The second purge-gas supplying unit 212 is provided at one side of a lower part of the sensing tube 111 and injects second purge gas into the sensing tube 111. Process gas such as ammonia may be used as the second purge gas. However, if the process gas is already used as the first purge, the inert gas may be used as the second purge gas. As necessary, the second purge-gas supplying unit 212 may be also provided with a second controller 222 such as the MFC or APC for control the flow or pressure of the first purge to gas to be injected into the sensing tube 111, so that the flow or pressure of the second purge gas can be controlled according to processes.

The CVD apparatus according to a second exemplary embodiment of the present invention can more effectively prevent the process gas from flowing back into the sensing tube 111 because a large amount of ammonia gas is discharged along with the purge gas through the sensing tube 111.

According to the first and second exemplary embodiments of the present invention, the CVD apparatus continuously discharges the purge gas or the ammonia gas from the inside of the sensing tube 111 to the outlet 112 of the sensing tube 111 at a lower end of the sensing tube 111, thereby preventing the process gas from being introduced into the sensing tube 111.

Thus, the non-contact type thermometer 200 can correctly sense the temperature of the substrate S or the susceptor 120 through the sensing tube 111, so that a film can be deposited with high quality.

Further, it is possible to enlarge the outlet 112 of the sensing tube 111, which has been formed as narrow as possible to prevent the process gas from being introduced into the sensing tube 111. As the outlet 112 of the sensing tube 111 is enlarged, the non-contact type thermometer 200 can employ a relatively inexpensive object lens having a low numerical aperture. Thus, even though the non-contact type thermometer 200 is relatively inexpensive and has a lower performance, its performance is enough to sense the temperature correctly.

Experimental results of the second exemplary embodiment of the present invention show that a conventional sensing tube's outlet having a diameter of 2.6 mm is almost similar in resolution and temperature-sensing performance of an optical pyrometer to a case of this embodiment where the outlet 112 is enlarged to have a diameter of 3.5 mm and the optical pyrometer has a numerical aperture lowered by 10% or more as compared with that of the conventional one.

Meanwhile, the non-contact type thermometer 200 and the sensing tube 111 according to the first and second exemplary embodiments of the present invention may be installed and formed in plural to sense the temperatures of the substrates S and susceptor 120 at plural positions.

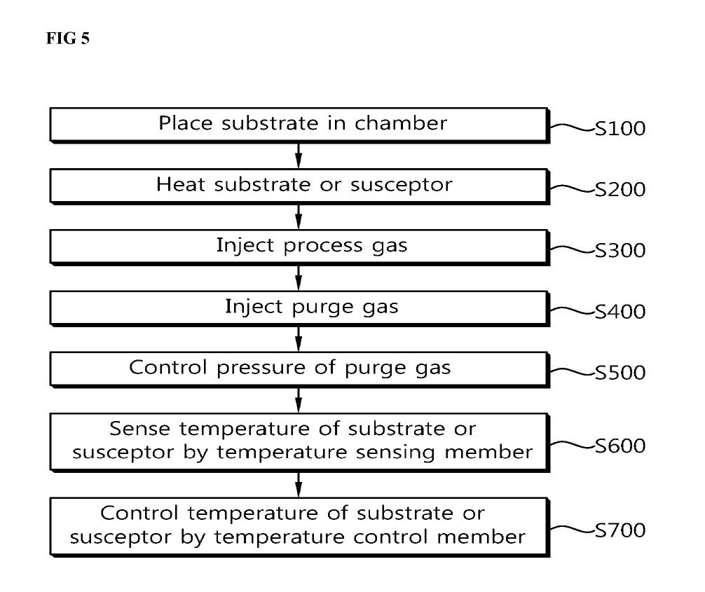

Below, a control method of a chemical vapor deposition (CVD) apparatus will be described according to an exemplary embodiment of the present invention. FIG. 5 is a flowchart of a control method of the CVD apparatus according to an exemplary embodiment of the present invention.

The control method of the CVD apparatus in this exemplary embodiment includes placing a substrate S on a susceptor 120 installed inside a chamber 100 at operation S100, heating the substrate S or the susceptor 120 at operation S200, injecting process gas into the chamber 100 at operation S300, injecting purge gas through the sensing tube 111 at operation S400, controlling the pressure of the purge gas at operation S500, sensing the temperature of the substrate S or the susceptor 120 through the sensing tube 111 at operation S600, and controlling the temperature of the substrate S or the susceptor 120 at operation S700.

In the CVD apparatus according to this exemplary embodiment, at least one substrate S is placed on the susceptor 120 inside the chamber 100 to perform a deposition process with regard to the substrate S at the operation S100.

A heater 130 for controlling the temperature heats the susceptor 120 and/or the substrate S at the operation S200. To heat the susceptor 120 and/or the substrate S, the heater 130 can vary from 600 to 1300 depending on temperatures required in the process. while group III and V process gas is supplied to the substrate S by way of example in the state that the substrate S is heated by the heater 130, a gallium nitride layer is grown on the substrate S at the operation S300.

Meanwhile, an epitaxial process for growing the gallium nitride layer is generally performed in manufacturing an light emitting diode (LED). In this case, the temperature of the substrate and the kind of the process gas are varied to grow a quantum-well layer. At this time, the change of the temperature has to be precisely performed to manufacture the LED with high quality.

Although the temperature is adjusted by the heater 130, the temperature sensing member 200 has to correctly sense the temperature of the substrate S or the susceptor 120 in order to effectively achieve a temperature adjustment of the heater 130.

However, during the process, some process gas may be introduced through the outlet 112 of the sensing tube 111 and deposited on the inner wall of the sensing tube 111 or the lens part of the temperature sensing member 200. In particular, if foreign materials are deposited on the lens part, there may be an error in a sensed temperature.

Accordingly, the purge gas such as nitrogen or hydrogen gas or ammonia gas, i.e., a part of the process gas is injected into the sensing tube 111, and discharged through the outlet 112 of the sensing tube 111, thereby preventing the process gas from flowing back into the sensing tube 111 through the outlet 112 of the sensing tube 111 at the operation S400.

To prevent the process gas from flowing back, if the nitrogen or hydrogen gas is massively injected into the sensing tube 111, a large amount of purge gas is injected into the process room and disturbs the epitaxial process itself. Therefore, a controller 220 such as a mass flow controller (MFC) or auto pressure controller (APC) for controlling the flow or pressure of the purge gas to be injected into the sensing tube 111 is provided to thereby control the flow or pressure of the purge gas according to processes at the operation S500.

With the foregoing configuration, the temperature sensing member 200 can correctly sense the temperature of the substrate S or the susceptor 120 at the operation S600. Further, the heater 130 can precisely control the temperature on the basis of the correctly-sensed temperature at the operation S700. In result, an LED device can be manufactured with high quality

While the present invention has been particularly shown and described with reference to exemplary embodiments thereof, it will be understood by those skilled in the art that various changes in form and details may be made therein without departing from the spirit and scope of the invention as defined by the appended claims. The exemplary embodiments should be considered in descriptive sense only and not for purposes of limitation. Therefore, the scope of the invention is defined not by the detailed description of the invention but by the appended claims, and all differences within the scope will be construed as being included in the present invention.

What is claimed is:

1. A chemical vapor deposition (CVD) apparatus comprising:
a chamber;
a susceptor which is provided inside the chamber and on which a substrate is placed;
a process-gas supplying unit which is placed above the susceptor and supplies process gas;
a sensing tube which is placed above the susceptor and opened toward the susceptor or the substrate;
a temperature sensing member which is installed at an end of the sensing tube and senses temperature of the susceptor or the substrate through the sensing tube; and
a purge-gas supplying unit which injects purge gas into the sensing tube.

2. The CVD apparatus of claim 1, wherein the purge gas injected into the sensing tube comprises one selected among nitrogen gas, hydrogen gas and ammonia gas.

3. The CVD apparatus of claim 1, wherein the purge-gas supplying unit further comprises a controller to control a supplying amount of the purge gas injected into the sensing tube.

4. The CVD apparatus of claim 1, wherein the sensing tube comprises a hollow structure penetrating the purge-gas supplying unit.

5. The CVD apparatus of claim 1, wherein the sensing tube comprises an outlet having a diameter smaller than an inner diameter of a body of the sensing tube.

6. The CVD apparatus of claim 1, further comprising a window between the sensing tube and the temperature sensing member.

7. The CVD apparatus of claim 6, wherein the window comprises quartz.

8. The CVD apparatus of claim 1, wherein the temperature sensing member comprises a non-contact type thermometer.

9. A chemical vapor deposition (CVD) apparatus comprising:
to a chamber;
a susceptor which is provided inside the chamber and on which a substrate is placed;
a process-gas supplying unit which is placed above the susceptor and supplies process gas;
a sensing tube which is placed above the susceptor and opened toward the susceptor or the substrate;
a temperature sensing member which is installed at an end of the sensing tube and senses temperature of the susceptor or the substrate through the sensing tube;
a first purge-gas supplying unit which injects first purge gas into the sensing tube; and
a second purge-gas supplying unit which injects second purge gas into the sensing tube.

10. The CVD apparatus of claim 9, wherein the fist purge gas comprises one of nitrogen gas and hydrogen gas, and the second purge gas comprises ammonia gas.

11. The CVD apparatus of claim 9, wherein the first purge-gas supplying unit further comprises a first controller to control a supplying amount of the first purge gas injected into the sensing tube, and the second purge-gas supplying unit further comprises a second controller to control a supplying amount of the second purge gas injected into the sensing tube.

12. The CVD apparatus of claim 9, wherein the sensing tube comprises a hollow structure penetrating the purge-gas supplying unit.

13. The CVD apparatus of claim 9, wherein the sensing tube comprises an outlet having a diameter smaller than an inner diameter of a body of the sensing tube.

14. The CVD apparatus of claim 9, further comprising a window at an upper end of the sensing tube.

15. The CVD apparatus of claim 14, wherein the window comprises quartz.

16. The CVD apparatus of claim 9, wherein the temperature sensing member comprises a non-contact type thermometer.

17. A method of controlling a chemical vapor deposition (CVD) apparatus, the method comprising:
placing a substrate on a susceptor provided inside a chamber;
heating the substrate and/or the susceptor;
injecting process gas into the chamber;
injecting purge gas into a sensing tube; and
sensing temperature of the substrate or the susceptor through the sensing tube.

18. The method of claim 17, wherein the purge gas injected into the sensing tube comprises one selected among nitrogen gas, hydrogen gas and ammonia gas.

19. The method of claim 17, further comprising controlling a supplying amount of the purge gas injected into the sensing tube.

20. The method of claim 17, further comprising controlling temperature of the substrate or susceptor.
